(19) United States
(12) Patent Application Publication
(10) Pub. No.: US 2016/0233176 A1
(43) Pub. Date: Aug. 11, 2016

(54) METHOD OF MANUFACTURING SEMICONDUCTOR DEVICE

(71) Applicant: Toyota Jidosha Kabushiki Kaisha, Toyota-shi Aichi-ken (JP)

(72) Inventor: Kunihito Kato, Nisshin-shi Aichi-ken (JP)

(73) Assignees: Toyota Jidosha Kabushiki Kaisha, Toyota-shi Aichi-ken (JP); Toyota Jidosha Kabushiki Kaisha, Toyota-shi Aichi-ken (JP)

(21) Appl. No.: 15/009,015

(22) Filed: Jan. 28, 2016

(30) Foreign Application Priority Data
Feb. 9, 2015 (JP) 2015-023219

(51) Int. Cl. H01L 23/00; H01L 23/12; H01L 21/48

(52) U.S. Cl. CPC H01L 23/562; H01L 21/4803; H01L 23/12

(57) ABSTRACT

A method for manufacturing a semiconductor device includes attaching a semiconductor substrate to a support substrate in a heated state, and processing the semiconductor substrate attached to the support substrate. The support substrate has a linear coefficient different from that of the semiconductor substrate. In an overlap region in which the support substrate overlaps the semiconductor substrate attached to the support substrate, a plurality of through-holes penetrating the support substrate from a front surface to a rear surface is provided. A straight line drawn on the front surface of the support substrate in any direction intersects with at least one of the through holes as long as the straight line is drawn through a center of the overlap region.

### CROSS-REFERENCE TO RELATED APPLICATION

This application claims priority to Japanese Patent Application No.2015-023219 filed on Feb. 9, 2015, the contents of which are hereby incorporated by reference into the present application.

### TECHNICAL FIELD

The technique disclosed in the present application relates to a method of manufacturing a semiconductor device.

### DESCRIPTION OF RELATED ART

In a manufacturing step of a semiconductor device, there is a case where a semiconductor substrate is attached to a support substrate in order to reinforce the semiconductor substrate. For example, manufacture of a semiconductor device with a thin thickness is enabled by thinning the semiconductor substrate after the semiconductor substrate has been attached to the support substrate.

Japanese Patent Application Publication No. 2011-23438 discloses a technique that creates a laminate substrate by attaching a semiconductor substrate to a support substrate while they are in a heated state. Since a linear expansion coefficient of the semiconductor substrate and a linear expansion coefficient of the support substrate differ, there is a risk that a warp might be generated in the laminate substrate when the laminate substrate thereafter returns to a normal temperature. In the technique of Japanese Patent Application Publication No. 2011-23438, a preset warp is provided in the support substrate before the attachment so as to prevent such a warp in the laminate substrate. Then, the semiconductor substrate is attached to the warped support substrate while they are in a heated state. Thereafter, when the laminate substrate is cooled, the laminate substrate is warped according to the difference in the linear expansion coefficients. This warp amends the preset warp that was provided in the support substrate. That is, the preset warp that was provided in the support substrate and the warp generated by the difference in the linear expansion coefficients act to cancel each other. As a result, a laminate substrate that is flat even after the cooling can be obtained.

### BRIEF SUMMARY

In the technique of Japanese Patent Application Publication No. 2011-23438, when the difference in the linear expansion coefficients of the semiconductor substrate and the support substrate is large, the warp to be provided in advance to the support substrate needs to be made large so as to cancel the warp that is to be generated by the difference in the linear expansion coefficients. Due to this, handling of the support substrate with such a large warp becomes difficult in the manufacturing step. Accordingly, in the present description, a technique that suppresses a warp in a laminate substrate by a different strategy from the technique of providing the warp in advance to the support substrate is provided.

A method for manufacturing a semiconductor device disclosed herein comprises attaching a semiconductor substrate to a support substrate in a heated state; and processing the semiconductor substrate attached to the support substrate. The support substrate has a linear expansion coefficient different from that of the semiconductor substrate. In an overlap region in which the support substrate overlaps the semiconductor substrate attached to the support substrate, a plurality of through-holes penetrating the support substrate from a front surface to a rear surface is provided. A straight line drawn on the front surface of the support substrate in any direction intersects with at least one of the through-holes as long as the straight line is drawn through a center of the overlap region.

Notably, the “center of the overlap region” as described above means a center of a region that is defined by a contour of the overlap region. More specifically, it means a position of a center of gravity in supposing that mass is distributed uniformly within the region defined by the contour of the overlap region. Further, “attaching a semiconductor substrate to a support substrate in a heated state” as described above may include heating the semiconductor substrate and the support substrate in separated states and attaching the semiconductor substrate to a surface of the support substrate while maintaining their heated states, and may include layering the semiconductor substrate on the support substrate, and attaching them by heating the semiconductor substrate and the support substrate while maintaining their layered state.

In this method, the semiconductor substrate is attached to the support substrate in the heated state. The semiconductor substrate and the support substrate contract upon when the semiconductor substrate and the support substrate are cooled after the attachment. Since the linear expansion coefficient of the support substrate differs from the linear expansion coefficient of the semiconductor substrate, a contracting amount of the support substrate differs from a contracting amount of the semiconductor substrate. As a result, stress is generated between the support substrate and the semiconductor substrate, and warp is generated in a laminate substrate thereof. Here, stress generated on the straight line passing through the center of the overlap region imposes the largest influence on the warp of the laminate substrate. The support substrate used in the method disclosed by the present description comprises the plurality of through holes. In this support substrate, when a focus is given to one straight line passing through the center of the overlap region, this one straight line intersects with one of the plurality of through holes. Accordingly, the support substrate is divided into a plurality by the through hole on the one straight line. Due to this, when the laminate substrate is cooled, stress is generated between the support substrate and the semiconductor substrate in each of the divided parts of the support substrate on the one straight line. Due to this, the stress generated on the one straight line is small as compared to that in a case where no through hole exists. As above, the straight line intersects with at least one of the plurality of through holes, no matter in which direction the straight line is drawn so as to pass through the center of the overlap region. Accordingly, the stress to be generated is reduced likewise in any of the straight lines passing through the center of the overlap region. Thus, according to this method, the warp in the laminate substrate can be suppressed.

### BRIEF DESCRIPTION OF DRAWINGS

FIG. 1 shows a schematic perspective view of a semiconductor substrate 60 and a support substrate 10;

FIG. 2 shows a planar view showing a lower surface 10a of the support substrate 10;

FIG. 3 shows a cross sectional view of the support substrate 10 at a straight line A3 of FIG. 2;

FIG. 4 shows a cross sectional view of the semiconductor substrate 60;

FIG. 5 is an explanatory diagram of a step of applying an adhesive 30 on the semiconductor substrate 60;

FIG. 6 is an explanatory diagram of a step of attaching the semiconductor substrate 60 on the support substrate 10;

FIG. 7 is an explanatory diagram of the step of attaching the semiconductor substrate 60 on the support substrate 10;

FIG. 8 is an explanatory diagram of a step of attaching the semiconductor substrate 60 on a support substrate 100 of a comparative example;

FIG. 9 is an explanatory diagram of the step of attaching the semiconductor substrate 60 on the support substrate 100 of the comparative example;

FIG. 10 is an explanatory diagram of a thinning step;

FIG. 11 is an explanatory diagram of an ion implantation step;

FIG. 12 is an explanatory diagram of a lower electrode forming step;

FIG. 13 shows a planar view of a lower surface 10a of a support substrate 10 of a variant; and

FIG. 14 shows a planar view of a lower surface 10a of a support substrate 10 of a variant.

### DETAILED DESCRIPTION

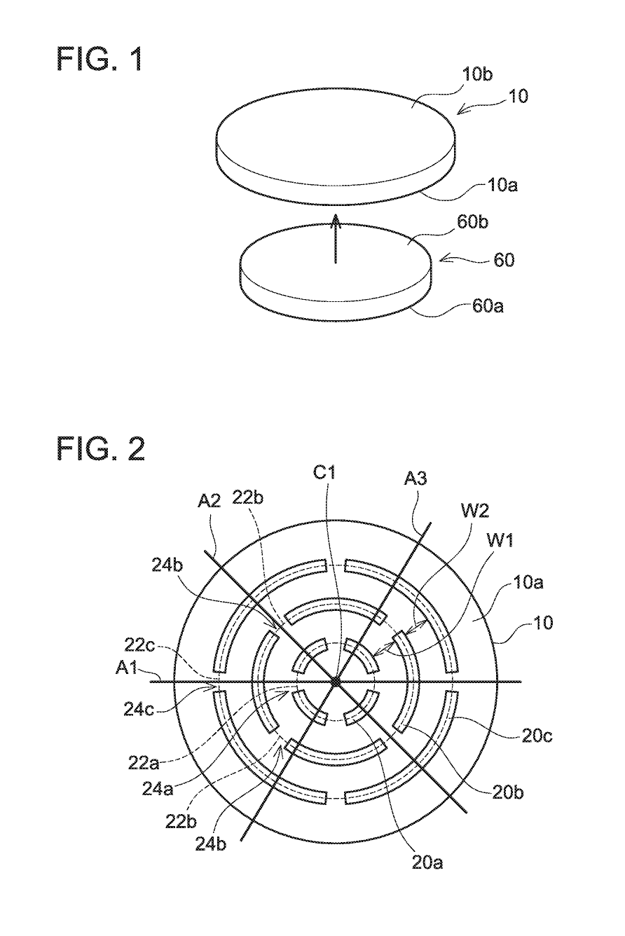

In a method of manufacturing a semiconductor device of the present embodiment, as shown in FIG. 1, a semiconductor substrate 60 is attached to a lower surface 10a of a support substrate 10 so as to reinforce the semiconductor substrate 60, and processing is performed on the reinforced semiconductor substrate 60. Notably, in FIG. 1, through holes that the support substrate 10 comprises are not depicted.

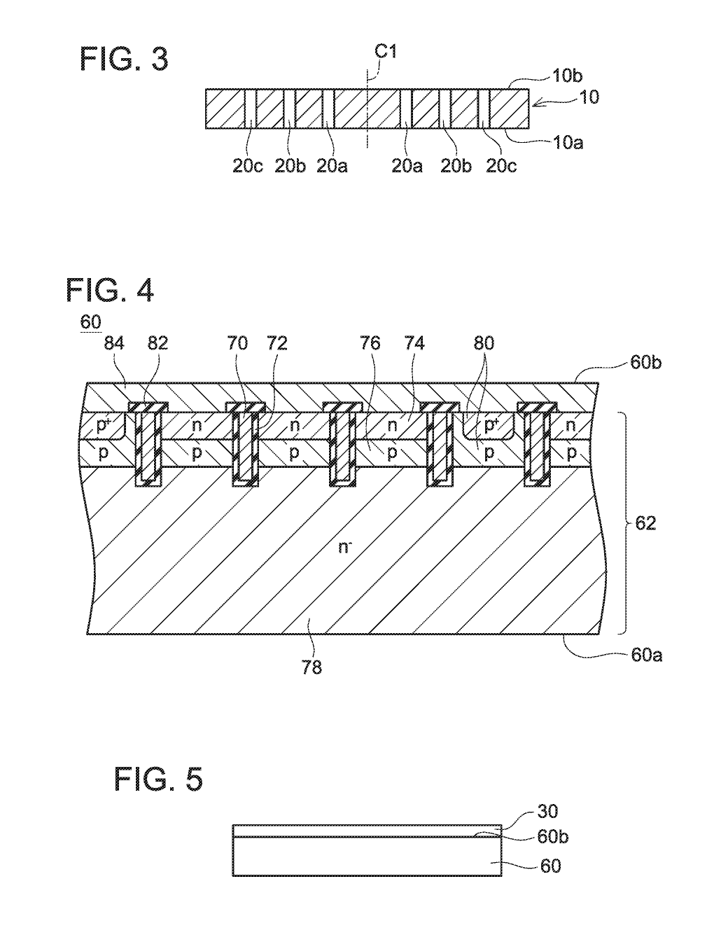

As shown in FIGS. 1 and 2, the support substrate 10 has a disk shape. The support substrate 10 is configured of a single crystal sapphire. The support substrate 10 has a thickness of about 700 μm. A linear expansion coefficient of the support substrate 10 (that is, sapphire) is about 5.2 ppm/K. The support substrate 10 comprises four through holes 20a, four through holes 20b, and four through holes 20c. As shown in FIG. 3, the through holes 20a, 20b, and 20c penetrate the support substrate 10 from its upper surface 10b to the lower surface 10a. A center point C1 shown in FIG. 2 shows a center of the support substrate 10 when the lower surface 10a of the support substrate 10 is seen in a planar view. The through holes 20a extend in an arcuate shape along a circle 22a having the center point C1 as a center. The plurality of through holes 20a are separated from each other by separating portions 24a (that is, regions where the through holes are not formed) on the circle 22a. The through holes 20b extend in an arcuate shape along a circle 22b (that is, a circle concentric to the circle 22a) having the center point C1 as a center. The plurality of through holes 20b are separated from each other by separating portions 24b (that is, regions where the through holes are not formed) on the circle 22b. The through holes 20c extend in an arcuate shape along a circle 22c (that is, a circle concentric to the circle 22a) having the center point C1 as a center. The plurality of through holes 20c are separated from each other by separating portions 24c (that is, regions where the through holes are not formed) on the circle 22c. The separating portions 24a and the separating portions 24c are arranged in same directions as seen from the center point C1. The separating portions 24b are arranged in directions that are different from the directions of the separating portions 24a, 24c as seen from the center point C1. Accordingly, as shown in FIG. 2, when the lower surface 10a is seen in the planar view, a straight line A1 that passes through the center point C1 and also through the separating portions 24a, 24c, intersects with the through holes 20b. Further, when the lower surface 10a is seen in the planar view, a straight line A2 that passes through the center point C1 and also through the separating portions 24b, intersects with the through holes 20a, 20c. Further, when the lower surface 10a is seen in the planar view, a straight line A3 that passes through the center point C1 but not through any of the separating portions 24a, 24b, 24c, intersects with the through holes 20a, 20b, and 20c. Accordingly, in the lower surface 10a, no matter in which direction a straight line is drawn so as to pass through the center point C1, this straight line intersects with at least one of the through holes 20a, 20b, and 20c. A gap W1 between the through holes 20a and the through holes 20b (that is, a difference of radius of the circle 22a and the radius of the circle 22b) is substantially equal to a gap W2 between the through holes 20b and the through holes 20c (that is, a difference of radius of the circle 22b and the radius of the circle 22c).

As shown in FIG. 1, the semiconductor substrate 60 has a disk shape. A diameter of the semiconductor substrate 60 is somewhat smaller than a diameter of the support substrate 10. As shown in FIG. 4, a part of a semiconductor device structure is constructed within the semiconductor substrate 60. The semiconductor substrate 60 comprises a silicon substrate 62, and electrodes and insulating layers provided on the silicon substrate 62. A linear expansion coefficient of the silicon substrate 62 is about 3.4 ppm/K. Since the semiconductor substrate 60 is mostly configured of the silicon substrate 62, a linear expansion coefficient of the semiconductor substrate 60 is substantially equal to the linear expansion coefficient of the silicon substrate 62. That is, the linear expansion coefficient of the semiconductor substrate 60 is smaller than the linear expansion coefficient of the support substrate 10. A plurality of trenches is provided on an upper surface of the silicon substrate 62, and a gate electrode 70 and a gate insulating film 72 are disposed within each trench. An n-type emitter region 74, a p-type body region 76, an n-type drift region 78, and p-type anode regions 80 are provided within the silicon substrate 62. A part of an IGBT is configured by the emitter region 74, the body region 76, the drift region 78, and the gate electrode 70, and a part of a diode is configured by the anode region 80 and the drift region 78. Interlayer insulating films 82 that cover the gate electrodes 70 are provided on the upper surface of the silicon substrate 62. Further, an upper electrode 84 is provided so as to cover the interlayer insulating films 82 and the upper surface of the silicon substrate 62. The upper electrode 84 comprises a structure in which AlSi, Ti, Ni, and Au are laminated from a silicon substrate 62 side. An upper surface of the upper electrode 84 configures an upper surface 60b of the semiconductor substrate 60, and the lower surface of the silicon substrate 62 configures a lower surface 60a of the semiconductor substrate 60. The semiconductor substrate 60 has a thickness of about 725 μm.

Next, a method of manufacturing a semiconductor device using the aforementioned support substrate 10 and semiconductor substrate 60 will be described. Firstly, as shown in FIG. 5, an adhesive 30 is applied to the upper surface 60b of the semiconductor substrate 60 (that is, on the upper surface of the upper electrode 84 shown in FIG. 4). The adhesive 30 is applied to an entire region of the upper surface 60b of the semiconductor substrate 60. The adhesive 30 is configured of polyimide resin. Here, the adhesive 30 is applied at a thickness of about 30 μm. Next, the semiconductor substrate 60 is thermally treated at 300° C. for about one hour. The adhesive 30 is hereby hardened. The thickness of the hardened adhesive 30 becomes about 20 μm. The hardened adhesive 30 (that is, hardened polyimide) has a thermally plastic property.

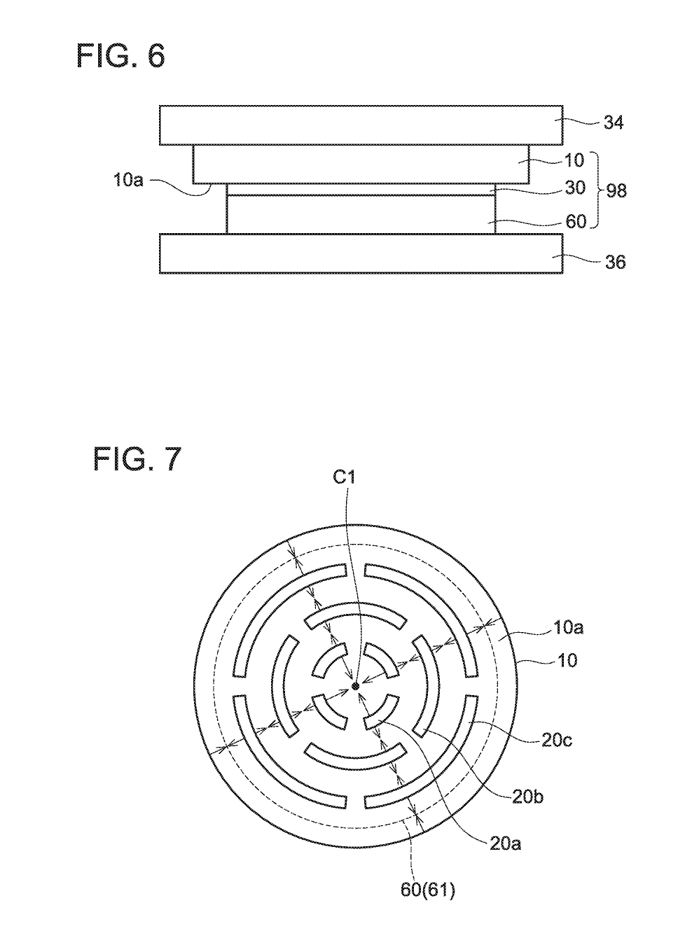

Next, as shown in FIG. 6, the support substrate 10 is arranged on the adhesive 30. That is, the support substrate 10 is layered on the semiconductor substrate 60. Here, the lower surface 10a of the support substrate 10 is brought to make contact with the adhesive 30. Further, a dotted line 60 in FIG. 7 shows a position of the semiconductor substrate 60 on the lower surface 10a of the support substrate 10. As shown in the drawings, the support substrate 10 is layered on the semiconductor substrate 60 so that the center point C1 of the support substrate 10 matches the center point of the semiconductor substrate 60. As above, when the support substrate 10 and the semiconductor substrate 60 are laminated, the through holes 20a, 20b, and 20c of the support substrate 10 are covered by the semiconductor substrate 60 (that is, the adhesive 30). That is, the through holes 20a, 20b, and 20c are closed by the adhesive 30. Hereinbelow, within the lower surface 10a of the support substrate 10, a region that overlaps with the semiconductor substrate 60 when seen along a laminate direction is termed an overlap region 61. That is, in FIG. 7, a region surrounded by the dotted line 60 is the overlap region 61. The support substrate 10 makes contact with the adhesive over an entirety of the overlap region 61. A center point of the overlap region 61 matches the center point C1 of the support substrate 10. Further, all of the through holes 20a, 20b, and 20c are included in the overlap region 61. Hereinbelow, a laminate in which the support substrate 10 and the semiconductor substrate 60 are laminated will be termed a laminate substrate 98. As shown in FIG. 6, when the semiconductor substrate 60 and the support substrate 10 are laminated, the laminate substrate 98 is sandwiched by pressing plates 34, 36 from above and under. Due to this, the laminate substrate 98 is pressurized in an up and down direction (laminate direction). That is, the support substrate 10 is pressed against the semiconductor substrate 60.

Next, as shown in FIG. 6, the laminate substrate 98 is heated while maintaining a state in which the laminate substrate 98 is pressurized. Here, the laminate substrate 98 is heated to a temperature higher than a glass transition temperature of the adhesive 30 (about 300° C.). Since the adhesive 30 itself is softened by the heating, the support substrate 10 makes tight contact with the adhesive 30. Next, the laminate substrate 98 is gradually cooled. The adhesive 30 hardens when the temperature of the laminate substrate 98 becomes lower than the glass transition temperature of the adhesive 30. Due to this, the semiconductor substrate 60 and the support substrate 10 are fixed to each other. That is, the semiconductor substrate 60 and the support substrate 10 are fixed over the entirety of the overlap region 61. Thereafter the cooling is continued until the laminate substrate 98 comes to a normal temperature.

Upon cooling the laminate substrate 98, the support substrate 10 and the semiconductor substrate 60 act to contract. Since the linear expansion coefficient of the support substrate 10 is larger than the linear expansion coefficient of the semiconductor substrate 60, the support substrate 10 acts to contract at a greater degree than the semiconductor substrate 60. Further, at a temperature that is lower than the glass transition temperature, the upper surface 60b of the semiconductor substrate 60 and the lower surface 10a of the support substrate 10 are fixed to each other by the adhesive 30. When the support substrate 10 acts to contract in a state where the semiconductor substrate 60 and the support substrate 10 are fixed to each other, the laminate substrate 98 acts to warp such that a semiconductor substrate 60 side becomes a convexed side. However, since the laminate substrate 98 is restrained by the pressing plates 34, 36, indeed no warp is generated in the laminate substrate 98. Due to this, stress is generated inside the laminate substrate 98. However, as will be described later, the stress generated in the laminate substrate 98 during the cooling is extremely small in the present embodiment.

When the laminate substrate 98 is cooled to the normal temperature, the pressing plates 34, 36 are opened and the laminate substrate 98 is taken out. When the pressing plates 34, 36 are opened, the internal stress in the laminate substrate 98 is released and warp is generated in the laminate substrate 98. However, in the present embodiment, since the stress generated in the laminate substrate 98 during the cooling is extremely small, so hardly any warp is generated in the laminate substrate 98.

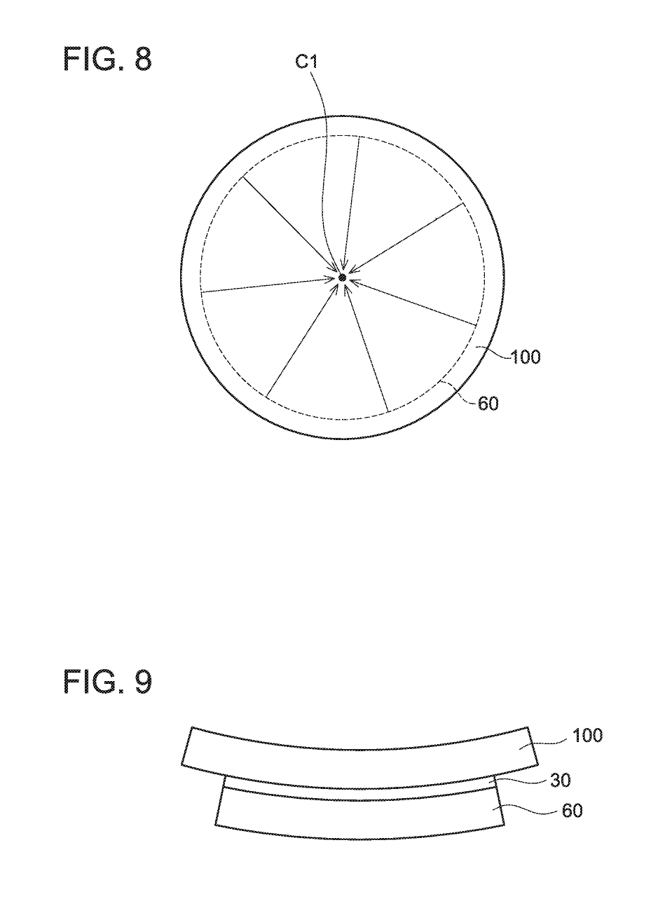

Next, the stress generated in the laminate substrate 98 during the cooling will be described in detail. Firstly, for comparison, as shown in FIG. 8, stress generated in a case of attaching the semiconductor substrate 60 to a support substrate 100 not having any through holes 20a, 20b, and 20c will be described. In this case, since the entirety of the upper surface 60b of the semiconductor substrate 60 is fixed to the support substrate 10, extremely high stress is generated between the semiconductor substrate 60 and the support substrate 10. More specifically, as shown in FIG. 8, by an arrow, the support substrate 100 acts to contract toward the center point C1 over its entire region in a radial direction of the overlap region 61 during the cooling of the laminate substrate. Due to this, an amount by which the support substrate 100 acts to contract in the radial direction is large, and large stress is generated in the laminate substrate. Due to this, when the pressing plates 34, 36 are opened and the stress in the laminate substrate is released, the support substrate 100 contracts at a great degree toward the center point C1, and as shown in FIG. 9, the laminate substrate acts to warp such that the semiconductor substrate 60 side becomes the convexed side. Since a contracting amount of the support substrate 100 is large, a warping amount of the laminate substrate becomes large.

Contrary to this, the support substrate 10 of the present embodiment comprises the through holes 20a, 20b, and 20c. As described above, all of the lines passing through the center point C1 of the support substrate 10 (that is, the center point of the overlap region 61) are configured to intersect with at least one of the through holes 20a, 20b, and 20c. That is, the support substrate 10 is divided in the radial direction by the through holes 20a, 20b, and 20c. Due to this, the stress is generated between the support substrate 10 and the semiconductor substrate 60 in each of the regions of the support substrate 10 divided in the radial direction. The stress generated in each of the divided narrow regions is smaller than the stress generated in the case where the support substrate 10 and the semiconductor substrate 60 are attached over the entire region in the radial direction as in FIG. 8. More specifically, when the support substrate 10 is divided in the radial direction, as shown in FIG. 7 by arrows, the support substrate 10 acts to contract in each of the divided portions in the radial direction upon cooling. Due to this, as compared to the case of FIG. 8 (that is, in the case where the support substrate does not have any through holes), according to the method of the present embodiment, the stress generated in the laminate substrate 98 upon the cooling is small. Thus, even when the stress in the laminate substrate 98 is released by opening the pressing plates 34, 36, the amount by which the support substrate 10 acts to contract toward the center point C1 is extremely small, and hardly any warp is generated in the laminate substrate 98. As above, according to the method of the present embodiment, the warp generated in the laminate substrate 98 after the cooling can be suppressed.

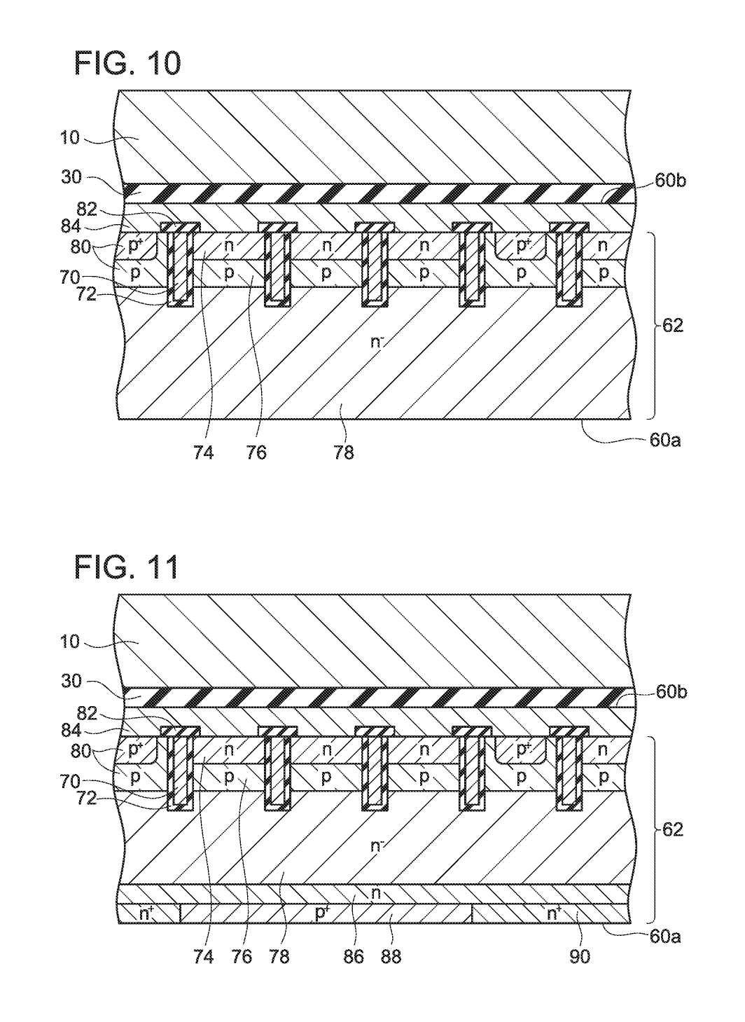

When the laminate substrate 98 is taken out from the pressing plates 34, 36, the lower surface 60a of the semiconductor substrate 60 is polished. Further, after the polishing, the lower surface 60a of the semiconductor substrate 60 is wet etched by hydrofluoric acid. By so doing, the semiconductor substrate 60 is thinned as shown in FIG. 10. Here, the semiconductor substrate 60 is thinned to a thickness of about 100 μm.

Next, p-type impurities and n-type impurities are selectively implanted to the lower surface of the silicon substrate 62 (that is, the lower surface 60a of the semiconductor substrate 60). Moreover, the implanted p-type impurities and n-type impurities are activated by laser annealing the lower surface of the silicon substrate 62. By so doing, an n-type buffer region 86, p⁺-type collector regions 88, and n⁺-type cathode regions 90 as shown in FIG. 11 are formed. Each IGBT is configured of the emitter region 74, the body region 76, the drift region 78, the buffer region 86, the collector region 88 and the gate electrode 70, and the like. Further, each diode is configured of the anode region 80, the drift region 78, the buffer region 86, and the cathode region 90.

Next, the laminate substrate 98 is put into a furnace and thermally treated at 300° C. By so doing, crystal defects generated in the silicon substrate 62 during the laser annealing are recovered.

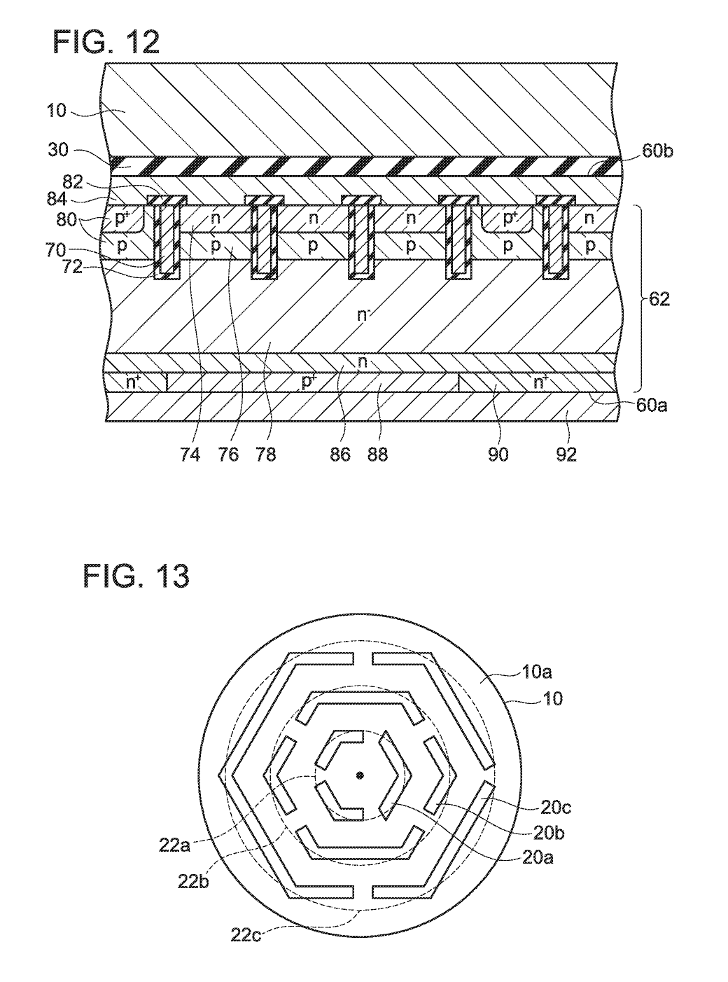

Next, as shown in FIG. 12, a lower electrode 92 is formed on the lower surface of the silicon substrate 62 by sputtering. Next, the semiconductor substrate 60 is detached from the support substrate 10. Next, the semiconductor substrate 60 is diced into chips. Semiconductor devices are thereby completed. Notably, the detached support substrate 10 can be reused after cleansing.

As described above, according to the method of the present embodiment, the warp being generated in the laminate substrate 98 after the cooling can be suppressed. Accordingly, after having attached the semiconductor substrate 60 on the support substrate 10, processing (that is, thinning, ion implantation, and the like) can suitably be performed on the semiconductor substrate 60.

Notably, even by the method of the present embodiment, slight warp may be generated in the laminate substrate 98. However, in such a case, for example, a technique that provides warp in the support substrate in advance as in Japanese Patent Application Publication No. 2011-23438 may be used in combination. By using the technique that provides warp in the support substrate in advance in combination with the method of the present embodiment, the amount of the warp to be provided in the support substrate in advance can be made small. Due to this, handling of the support substrate becomes easy.

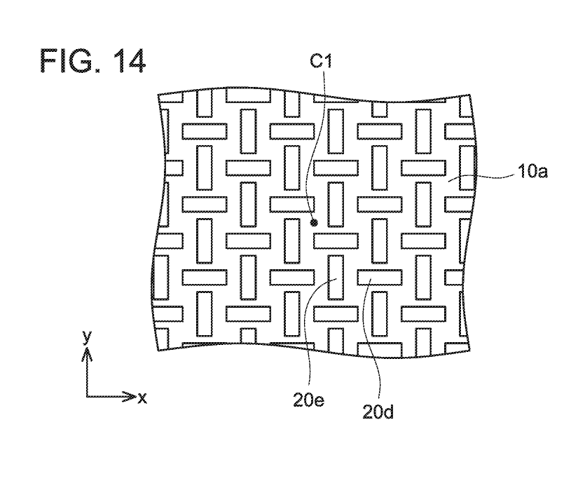

Notably, in the aforementioned embodiment, the through holes 20a, 20b, and 20c are given arcuate shapes extending along the concentric circles 22a, 22b, and 22c. By configuring the through holes 20a, 20b, and 20c as above, the contraction of the support substrate 10 in the radial direction can more efficiently be suppressed. Further, as shown in FIG. 13, the through holes 20a, 20b, and 20c may be formed in polyline shapes extending along the concentric circles 22a, 22b, and 22c. Even with such configurations, substantially the same effect as with the arcuate-shaped through holes can be achieved. Further, the through holes may be arranged as shown in FIG. 14. In FIG. 14, through holes 20d and 20e are opened on the lower surface 10a of the support substrate 10 within the overlap region 61. The through holes 20d extend longer in an x direction on the lower surface 10a, and the through holes 20e extend longer in a y direction that vertically intersects with the x direction on the lower surface 10a. The through holes 20d and 20e are arranged in a matrix along the x and y directions on the lower surface 10a. The through holes 20d and the through holes 20e are arranged alternately when seen along the x direction, and the through holes 20d and the through holes 20e are arranged alternately when seen along the y direction. Due to this, through holes 20e are arranged at positions adjacent to each through hole 20d, and through holes 20d are arranged at positions adjacent to each through hole 20e. In such a configuration also, the straight lines passing through the center point C1 intersects with at least one of the through holes 20d and 20e, so the contraction of the support substrate 10 can suitably be suppressed.

Notably, in the aforementioned embodiment, the case in which the linear expansion coefficient of the support substrate 10 is larger than the linear expansion coefficient of the semiconductor substrate 60 has been described. However, the linear expansion coefficient of the support substrate 10 may be smaller than the linear expansion coefficient of the semiconductor substrate 60. In this case, when the laminate substrate is taken out from the pressing plates after cooling, the semiconductor substrate 60 contracts at a greater degree than the support substrate 10. However, since the support substrate 10 is divided into a plurality by the through holes 20 in the radial direction, each of the divided portions can move accompanying the contraction of the semiconductor substrate 60. Further, in each of the divided portions, warp will be generated due to the difference in the contraction amounts of the support substrate 10 and the semiconductor substrate 60, however, the warp generated in each of the divided portions is extremely small. Due to this, the warp in the laminate substrate 98 can be suppressed.

Notably, in the aforementioned embodiment, the laminate substrate 98 is heated in a state where the semiconductor substrate 60, the adhesive 30, and the support substrate 10 are laminated, and the semiconductor substrate 60 is attached to the support substrate 10 as a consequence thereof. However, the support substrate 10 and the semiconductor substrate 60 may be heated separately, and the support substrate 10 may be attached to the semiconductor substrate 60 via the adhesive 30 in such heated state.

Further, in the aforementioned embodiment, the center point of the overlap region 61 matched the center point C1 of the support substrate 10, however, these center points may not necessarily be matched.

Further, in the aforementioned embodiment, the semiconductor substrate 60 is attached to the support substrate 10 via the adhesive 30. However, the semiconductor substrate 60 may be attached to the support substrate 10 by other methods, such as using another adhesive such as a heat-curing adhesive.

Further, in the aforementioned embodiment, planar shapes of the semiconductor substrate 60 and the support substrate 10 are substantially circular, however, these may not necessarily be circular.

Further, in the aforementioned embodiment, the semiconductor substrate 60 is configured mainly of silicon. However, the semiconductor substrate 60 may be configured of other semiconductors, such as SiC, or GaN.

Further, in the aforementioned embodiment, the sapphire substrate is used as the support substrate 10. Since sapphire has transparency, it is superior in being enabling visual confirmation of the surface of the semiconductor substrate 60 even after the support substrate 10 has been attached. However, materials other than sapphire may be used as the support substrate 10.

Further, in the aforementioned embodiment, the gap W1 between the through holes 20a and the through holes 20b is substantially equal to the gap W2 between the through holes 20b and the through holes 20c. However, the gap W1 and the gap W2 may be different. For example, the gap W2 on an outer circumferential side may be wider than the gap W1 on an inner circumferential side.

Relationships of the constituent elements of the aforementioned embodiment and the constituent element of the claims will be described below. The semiconductor substrate 60 of the embodiment is an example of a semiconductor substrate in the claims. The support substrate 10 of the embodiment is an example of a support substrate in the claims. The through holes 20a to 20e of the embodiment are examples of through holes in the claims. The overlap region 61 of the embodiment is an example of an overlap region in the claims. The center point C1 of the embodiment is an example of a center of the overlap region in the claims. The straight lines A1, A2, and A3 of the embodiment are examples of straight lines in the claims. The through holes 20a of the embodiment are an example of a group of first through holes in the claims. The through holes 20b of the embodiment are an example of a group of second through holes in the claims. The through holes 20d of the embodiment are an example of a group of third through holes in the claims. The through holes 20e of the embodiment are an example of a group of fourth through holes in the claims.

Technical elements disclosed in the description will be listed below. Notably, each of the technical elements herein are solely independent and useful on its own.

In one aspect of the method disclosed herein, the linear expansion coefficient of the support substrate may be larger than the linear expansion coefficient of the semiconductor substrate.

In one aspect of the method disclosed herein, the plurality of through-holes may comprise a group of first through-holes extending intermittently along a first circle around the center; and a group of second through-holes extending intermittently along a second circle around the center. A radius of the first circle may be different from a radius of the second circle.

Notably, the group of first through holes may extend in an arcuate shape along the first circle, or may extend in a polyline shape along the first circle. Further, the group of second through holes may extend in an arcuate shape along the second circle, or may extend in a polyline shape along the second circle.

In one aspect of the method disclosed herein, the plurality of through-holes may comprise a group of third through-holes extending along a first direction, and a group of fourth through-holes extending along a second direction intersecting the first direction. The third through-holes and the fourth through-holes may be arranged in a matrix along the first and second directions so that each of the third through-holes is adjacent to one of the fourth through-holes and each of the fourth through-holes is adjacent to one of the third through-holes.

The embodiments have been described in detail in the above. However, these are only examples and do not limit the scope of claims. The technology described in the claims includes various modifications and changes of the concrete examples represented above. The technical elements explained in the present description or drawings exert technical utility independently or in combination of some of them, and the combination is not limited to one described in the claims as filed. Moreover, the technology exemplified in the present description or drawings achieves a plurality of objects at the same time, and has technical utility by achieving one of such objects.

1. A method for manufacturing a semiconductor device, the method comprising:
attaching a semiconductor substrate to a support substrate in a heated state; and
processing the semiconductor substrate attached to the support substrate,
wherein
the support substrate has a linear expansion coefficient different from a linear expansion coefficient of the semiconductor substrate,
in an overlap region in which the support substrate overlaps the semiconductor substrate attached to the support substrate, a plurality of through holes penetrate the support substrate from a front surface to a rear surface, and
a straight line drawn through a center of the overlap region and on the front surface of the support substrate in any direction intersects with at least one of the through holes.

2. The method of claim 1, wherein the linear expansion coefficient of the support substrate is larger than the linear expansion coefficient of the semiconductor substrate.

3. The method of claim 1, wherein
the plurality of through holes comprises:
a group of first through holes extending intermittently along a first circle around the center of the overlap region; and
a group of second through holes extending intermittently along a second circle around the center of the overlap region, and
a radius of the first circle is different from a radius of the second circle.

4. The method of claim 1, wherein
the plurality of through holes comprises:
a group of third through holes extending along a first direction; and
a group of fourth through holes extending along a second direction intersecting the first direction, and
the third through holes and the fourth through holes are arranged in a matrix along the first and second directions so that each of the third through holes is adjacent to one of the fourth through holes and each of the fourth through holes is adjacent to one of the third through-holes.
